(19) United States
(12) Patent Application Publication
(10) Pub. No.: US 2010/0066683 A1
(43) Pub. Date: Mar. 18, 2010

(54) Method for Transferring Thin Film to Substrate

(76) Inventors: Shih-Chang CHANG, Chutung (TW); Lili Huang, San Jose, CA (US); Steve Porter Hotelling, San Jose, CA (US)

Correspondence Address: APPLE C/O MORRISON AND FOERSTER ,LLP;LOS ANGELES, 555 WEST FIFTH STREET SUITE 3500, LOS ANGELES, CA, 90013-1024, US

(21) Appl. No.: 12/212,478

(22) Filed: Sep. 17, 2008

(51) Int. Cl. G06F 3/041; H01L 21/00

(52) U.S. Cl. 345/173; 438/53; 257/E21.001

(57) ABSTRACT

A method for transferring single layer thin film from a temporary substrate to a target substrate is disclosed. A base layer may be fabricated onto a fabrication sheet. A single layer thin film of conductive material may be patterned onto the base layer. A temporary transfer substrate may be adhered to the single layer thin film. The fabrication sheet may be removed and the base layer-patterned single layer thin film-temporary transfer substrate block transferred to a target substrate, where the base layer may contact the target substrate. Upon completion of the transfer, the temporary transfer substrate may be removed.

### FIELD OF THE INVENTION

This relates generally to the transfer of a thin film to a target substrate, and more particularly, to the transfer of a single layer thin film of conductive material from a temporary surface to a touch sensitive surface.

### BACKGROUND OF THE INVENTION

Many types of input devices are presently available for performing operations in a computing system, such as buttons or keys, mice, trackballs, touch sensor panels, joysticks, touch screens, and the like. Touch screens, in particular, are becoming increasingly popular because of their ease and versatility of operation as well as their declining price. Touch screens can include a touch sensor panel, which can be a clear panel with a touch-sensitive surface, and a display device, such as an LCD panel, that can be positioned partially or fully behind the touch sensor panel so that the touch-sensitive surface can cover at least a portion of the viewable area of the display device. Touch screens can allow a user to perform various functions by touching the touch sensor panel using a finger, stylus or other object at a location dictated by a user interface (UI) being displayed by the display device. In general, touch screens can recognize a touch event and the position of the touch event on the touch sensor panel, and a computing system can then interpret the touch event in accordance with the display appearing at the time of the touch event, and thereafter can perform one or more actions based on the touch event.

In some embodiments, a touch sensor panel can be implemented as an array of pixels formed by conductive material, such as indium tin oxide (ITO), patterned into multiple drive lines crossing over multiple sense lines and separated from each other by a dielectric material. The conductive material can be disposed on a back side of the touch-sensitive surface in order to detect a touch received on the front side of the touch-sensitive surface. The drive lines and sense lines can be formed on opposite sides of a substrate. Alternatively, the drive lines and sense lines can be formed adjacent to or near each other on the same layer on a single side of a substrate. Typical substrates for the conductive material can be made of glass or some other transparent substrate sturdy enough to fabricate the drive and sense lines directly thereon. However, with the increasing desire for smaller, thinner, flexible, and non-flat touch sensor panels, it can be difficult and expensive to fabricate the drive and sense lines directly on the substrates required for such panels.

### SUMMARY OF THE INVENTION

This relates to the transfer of single layer thin film of conductive material from a temporary substrate to a target substrate used in devices such as touch sensor panels. In some embodiments, transfer can be achieved by fabricating a block including a base layer, a single layer of thin film, and a temporary substrate, transferring the block to a target substrate, and removing the temporary substrate. In some embodiments, transfer can be achieved by fabricating a large block including a base layer, a single layer of thin film, and a temporary substrate, cutting the large block into smaller individual blocks, transferring each small individual block to a target substrate, and removing the temporary substrate from each small individual block.

### BRIEF DESCRIPTION OF THE DRAWINGS

FIG. 1a illustrates an exemplary thin film block having a fabrication sheet with a base layer on a surface of the sheet according to embodiments of the invention.

FIG. 1b illustrates the exemplary thin film block shown in FIG. 1a patterned with a single layer of thin film on a surface of the base layer according to embodiments of the invention.

FIG. 1c illustrates the exemplary thin film block shown in FIG. 1b having a transfer layer adhered to the patterned single layer of thin film with a removable adhesive according to embodiments of the invention.

FIG. 1d illustrates the exemplary thin film block shown in FIG. 1c with the fabrication sheet removed therefrom according to embodiments of the invention.

FIG. 1e illustrates an exemplary substrate having the exemplary thin film block shown in FIG. 1d transferred to a surface of the substrate and adhered thereto with a permanent adhesive according to embodiments of the invention.

FIG. 1f illustrates the exemplary substrate and thin film block shown in FIG. 1e with the transfer layer removed from the thin film block according to embodiments of the invention.

FIG. 2 illustrates an exemplary method for transferring a thin film to a substrate according to embodiments of the invention.

FIG. 3 illustrates another exemplary method for transferring a thin film to a substrate according to embodiments of the invention.

FIG. 4a illustrates an exemplary curved substrate having an exemplary thin film block transferred to a concave surface of the substrate and adhered thereto with a permanent adhesive according to embodiments of the invention.

FIG. 4b illustrates an exemplary curved substrate having an exemplary thin film block transferred to a convex surface of the substrate and adhered thereto with a permanent adhesive according to embodiments of the invention.

FIG. 4c illustrates an exemplary substrate having a convex surface and a flat surface with an exemplary thin film block transferred to the flat surface of the substrate and adhered thereto with a permanent adhesive according to embodiments of the invention.

FIG. 4d illustrates an exemplary substrate having a concave surface and a flat surface with an exemplary thin film block transferred to the flat surface of the substrate and adhered thereto with a permanent adhesive according to embodiments of the invention.

FIG. 5a illustrates an exemplary thin film block having a fabrication sheet with a base layer on a surface of the sheet according to embodiments of the invention.

FIG. 5b illustrates the exemplary thin film block shown in FIG. 5a patterned with two separated single layers of thin film on a surface of the base layer according to embodiments of the invention.

FIG. 5c illustrates the exemplary thin film block shown in FIG. 5b having a transfer layer adhered to the outermost of the patterned single layers of thin film with a removable adhesive according to embodiments of the invention.

FIG. 5d illustrates the exemplary thin film block shown in FIG. 5c with the fabrication sheet removed therefrom according to embodiments of the invention.

FIG. 5e illustrates an exemplary substrate having the exemplary thin film block shown in FIG. 5d transferred to a surface of the substrate and adhered thereto with a permanent adhesive according to embodiments of the invention.

FIG. 5f illustrates the exemplary substrate and thin film block shown in FIG. 5e with the transfer layer removed from the thin film block according to embodiments of the invention.

FIG. 6 illustrates another exemplary method for transferring a thin film to a substrate according to embodiments of the invention.

FIG. 7a illustrates an exemplary mobile telephone having a touch sensor panel that includes a thin film transferred thereon according to embodiments of the invention.

FIG. 7b illustrates an exemplary digital media player having a touch sensor panel that includes a thin film transferred thereon according to embodiments of the invention.

FIG. 7c illustrates an exemplary computer having a touch sensor panel that includes a thin film transferred thereon according to embodiments of the invention.

FIG. 8 illustrates an exemplary computing system including a touch sensor panel utilizing a thin film transferred thereon according to embodiments of the invention.

### DETAILED DESCRIPTION OF THE PREFERRED EMBODIMENT

In the following description of preferred embodiments, reference is made to the accompanying drawings which form a part hereof, and in which it is shown by way of illustration specific embodiments in which the invention may be practiced. It is to be understood that other embodiments may be utilized and structural changes may be made without departing from the scope of the preferred embodiments of the invention.

This relates to the transfer of single layer thin films of conductive material to substrates used in devices such as touch sensor panels. In some embodiments, transfer can be achieved by patterning a single layer of conductive material on one side of a transfer substrate and then transferring the patterned material from the transfer substrate onto a target substrate. This advantageously allows the patterned material to be transferred to any target substrate, where the target substrate may be one that either cannot withstand the standard fabrication process, e.g., a soft plastic substrate or a very thin substrate, or cannot fit the standard fabrication equipment, e.g., a non-flat substrate.

Although embodiments of this invention are described and illustrated herein in terms of touch sensor panels, it should be understood that embodiments of this invention are not so limited to such panels, but are generally applicable to panels utilizing other touch and proximity sensing technologies, and any substrate onto which a fabricated thin film may be transferred.

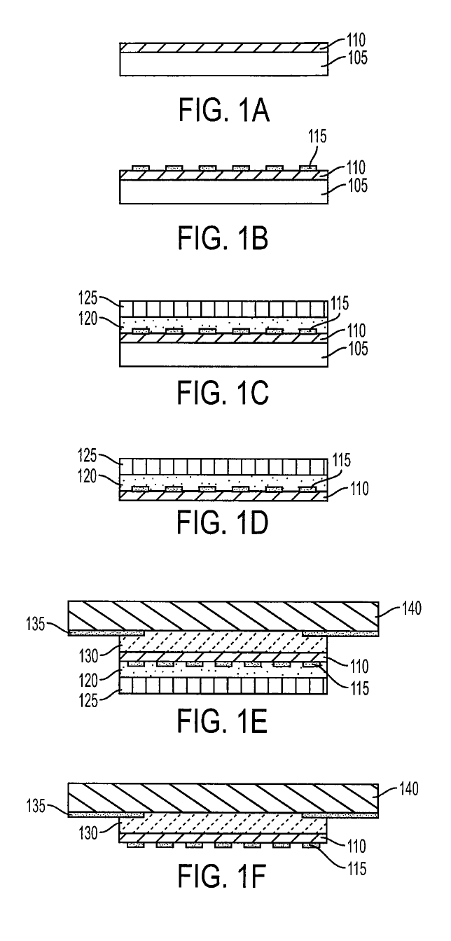

FIG. 1a illustrates an exemplary thin film block having a fabrication sheet with a base layer on a surface of the sheet according to embodiments of the invention. In the example of FIG. 1a, sheet 105 has base layer 110 disposed on a surface. The sheet 105 may include glass or any other suitable material capable of providing a temporary platform on which to fabricate a thin film block and then being easily removed from the block. The base layer 110 may include etch stopping material, such as silicon nitride, silicon dioxide, or any other suitable material that is inert to chemicals, e.g., hydrogen fluoride, that can be used to remove the sheet 105 by chemical etching. The base layer 110 may be deposited on the surface of the sheet 105 with a plasma-enhanced chemical vapor deposition (PECVD) or any other suitable deposition method. The base layer 110 may be rigid, semi-rigid, flexible, or deformable, depending on the application of the thin film block.

FIG. 1b illustrates the exemplary thin film block shown in FIG. 1a patterned with a single layer of thin film on a surface of the base layer according to embodiments of the invention. In the example of FIG. 1b, patterns of thin film 115 may be deposited as a single layer on a surface of the base layer 110. The thin film patterns may be used as conductive traces for carrying signals and may include transparent materials, such as single-layer indium tin oxide (SITO). Although SITO may be referred to herein for illustrative purposes, it is to be understood that other conductive materials can also be used according to embodiments of the invention. The thin film patterns may form portions of touch sensors for carrying images of touch in a touch sensitive device, such as a touch panel. The patterned thin film 115 may be deposited on a surface of the base layer 110 using sputtering or any other suitable method for disposing the patterned thin film onto the base layer.

FIG. 1c illustrates the exemplary thin film block shown in FIG. 1b having a transfer layer adhered to the patterned single layer of thin film with a removable adhesive according to embodiments of the invention. In the example of FIG. 1c, a layer of removable adhesive 120 may coat the patterned thin film 115. The removable adhesive 120 may include water-insoluble glue or any other suitable material capable of temporarily adhering two layers together and then being dissolved or otherwise removed. Transfer layer 125 may be placed on top of the removable adhesive 120, which helps to adhere the transfer layer to the underlying patterned thin film 115. The transfer layer 125 may include a polymer, such as polyethylene terephthalate (PET), or any other suitable material capable of supporting a thin film block for transfer to a substrate according to embodiments of the invention. The transfer layer 125 may be laminated or otherwise placed on the removable adhesive 120. The transfer layer 125 may be rigid, semi-rigid, flexible, or deformable, depending on the application of the thin film block.

FIG. 1d illustrates the exemplary thin film block shown in FIG. 1c with the fabrication sheet removed therefrom according to embodiments of the invention. In the example of FIG. 1d, the sheet 105 may be removed in preparation for transferring the thin film block to a substrate. The sheet 105 may be removed by chemical etching using a chemical such as hydrogen fluoride. Alternatively, the sheet 105 may be removed by mechanical methods or combination chemical-mechanical methods.

FIG. 1e illustrates an exemplary substrate having the exemplary thin film block shown in FIG. 1d transferred to a surface of the substrate and adhered thereto with a permanent adhesive according to embodiments of the invention. In the example of FIG. 1e, a layer of permanent adhesive 130 may be laminated or otherwise adhered to the base layer 110 of the thin film block. The permanent adhesive 130 may be adhered to the surface of the base layer 110 opposite the base layer surface onto which the patterned thin film 115 is disposed. The permanent adhesive 130, along with the thin film block, may be laminated or otherwise adhered to a surface of substrate 140. Accordingly, the stacking order may be the substrate 140, the permanent adhesive 130, the base layer 110, the patterned thin film 115, the removable adhesive 120, and the transfer layer 125. Optionally, opaque material 135 may be adhered to the edges of the substrate 140 and the permanent adhesive 130 to provide an aesthetic border for the substrate. The permanent adhesive 130 may include water-insoluble glue or any other suitable material capable of permanently adhering two layers together. The substrate 140 may include glass, plastic, or any other transparent material. The substrate 140 may be rigid, semi-rigid, flexible, or deformable, depending on the application of the substrate. In some embodiments, the substrate 140 may be a cover material for a touch sensitive device, in which a front side of the substrate 140 can receive a touch and a back side of the substrate can have the thin film block transferred thereto to detect the received touch.

FIG. 1f illustrates the exemplary substrate and thin film block shown in FIG. 1e with the transfer layer removed from the thin film block according to embodiments of the invention. In the example of FIG. 1f, the transfer layer 125 may be removed from the patterned thin film 115 by delaminating or otherwise removing the transfer layer from the removable adhesive 120 and then dissolving or otherwise removing the removable adhesive from the thin film. Alternatively, the removable adhesive 120 may be dissolved or otherwise removed from the thin film, thereby removing the transfer layer 125 with it. The resulting substrate and thin film block may now be ready for further processing. In some embodiments, a flex circuit may be bonded to the patterned thin film 115 at one end and an anti-reflective film may be laminated or otherwise coated over the patterned thin film 115 to further form a touch sensitive device. Optionally, one or more gaskets may be attached to the anti-reflective film to provide connections for other components of the touch sensitive device.

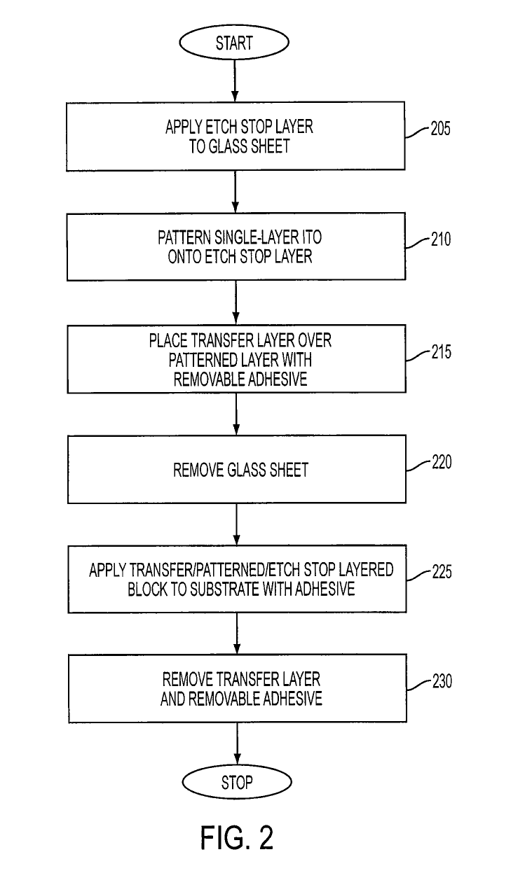

FIG. 2 illustrates an exemplary method for transferring a thin film to a substrate according to embodiments of the invention. A glass sheet may be provided as a temporary platform upon which to fabricate a transferable thin film block. An etch stop layer (e.g., base layer 110 in FIG. 1a) may be applied to the glass sheet (205). The etch stop layer may be deposited, laminated, or otherwise applied to the sheet. A single layer of thin film may be patterned on a surface of the etch stop layer (210). The patterned thin film may be SITO, for example. A transfer layer may be adhered to the patterned single layer with a removable adhesive (215). The removable adhesive may be applied to the patterned thin film and then the transfer layer laminated or otherwise placed on top of the removable adhesive.

After the transferable thin film block has been fabricated, the glass sheet may be removed (220). To do so, the thin film block may be exposed to an etching chemical that can etch away the glass sheet. The etch stop layer can protect the rest of the thin film block from chemical damage. Alternatively, a mechanical method may be used to remove the glass sheet. The remaining thin film block, comprising the transfer layer, removable adhesive, patterned thin film, and etch stop layer, may be transferred to a substrate and adhered thereto using a permanent adhesive (225). The permanent adhesive may be laminated or otherwise adhered to the etch stop layer and then laminated or otherwise adhered to a surface of the substrate. As such, the etch stop layer may be closest to the substrate, followed by the patterned thin film, followed by the removable adhesive, and the transfer layer farthest from the substrate.

The transfer layer and removable adhesive may be removed from the patterned thin film (230). The removable adhesive may be dissolved in solvent or otherwise removed, thereby removing the transfer layer with it. Alternatively, the transfer layer may be delaminated or otherwise removed from the removable adhesive and then the removable adhesive dissolved or otherwise removed from the patterned thin film. The resulting substrate-thin film block combination may be further processed to provide a suitable circuit.

In an alternate embodiment, the etch stop layer may be replaced with a plastic or polyimide layer that can be bonded to the glass sheet. The glass sheet may then be removed from the thin film block by de-bonding the sheet from the plastic or polyimide layer.

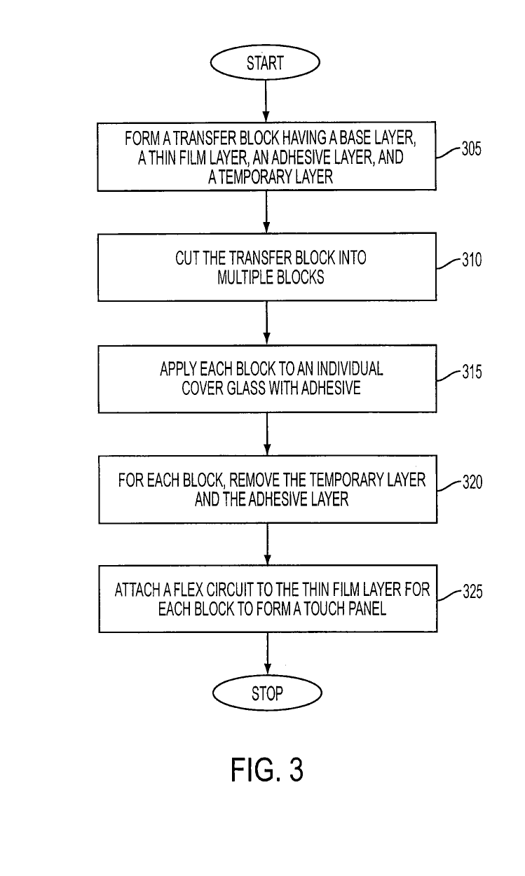

FIG. 3 illustrates another exemplary method for transferring a thin film to a substrate according to embodiments of the invention. For cost effectiveness, multiple thin film blocks may be fabricated at once on a large glass sheet and then separated for transfer to individual substrates. In the example of FIG. 3, a large glass sheet may be provided upon which to fabricate multiple thin film blocks from a large thin film block. The large thin film block may be fabricated on the glass sheet (305). The large thin film block may have a base layer formed on the glass sheet, a single layer of thin film, e.g., SITO, patterned on a surface of the base layer, a removable adhesive layer formed on the patterned thin film, and a transfer layer formed on the removable adhesive layer. The large thin film block may be fabricated using the method of FIG. 2, for example.

The glass sheet and the thin film block fabricated thereon may be die-cut into multiple smaller blocks (310). The smaller blocks may be cut to any size suitable for transfer to a substrate. Each smaller block may include a portion of the glass sheet, a portion of the base layer formed on the glass sheet portion, a portion of the patterned thin film formed on the base layer portion, a portion of the removable adhesive formed on the patterned thin film portion, and a portion of the transfer layer formed on the removable adhesive portion.

For each smaller block, the glass sheet portion may be removed using the method of FIG. 2, for example. The remainder of the thin film smaller block may be applied to an individual cover glass with a permanent adhesive (315). The thin film smaller block may be applied using the method of FIG. 2, for example. The transfer layer and removable adhesive may be removed from the patterned thin film (320) using the method of FIG. 2, for example. A flex circuit may be attached to the patterned thin film to form a touch panel, where the cover glass may receive a touch and the thin film block attached thereto may detect the touch (325). Optionally an anti-reflective layer or any other suitable layer may coat the patterned thin film and a gasket may be attached thereto to connect other components.

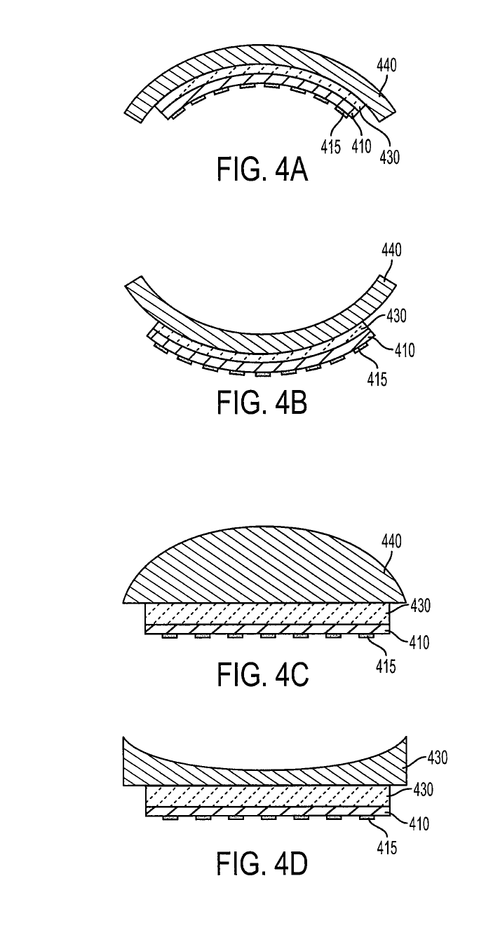

FIGS. 4a-4d illustrate exemplary curved substrates having exemplary thin film blocks transferred thereto according to embodiments of the invention. In the example of FIG. 4a, base layer 410 may be adhered to a concave surface of curved substrate 440 by a permanent adhesive 430. Patterned single layer thin film 415 may be disposed on a surface of the base layer 410. In the example of FIG. 4b, base layer 410 may be adhered to a convex surface of curved substrate 440 by a permanent adhesive 430. Patterned single layer thin film 415 may be disposed on a surface of the base layer 410. In the example of FIG. 4c, curved substrate 440 may have a convex surface and a flat surface opposite the convex surface. The base layer 410 may be adhered to the flat surface of the curved substrate 440 by a permanent adhesive 430. Patterned single layer thin film 415 may be disposed on a surface of the base layer 410. In the example of FIG. 4d, curved substrate 440 may have a concave surface and a flat surface opposite the concave surface. The base layer 410 may be adhered to the flat surface of the curved substrate 440 by a permanent adhesive 430. Patterned single layer thin film 415 may be disposed on a surface of the base layer 410.

The curved substrate may be rigid, semi-rigid, flexible, or deformable. The rigid curved substrate may be permanently formed into the curve. The semi-rigid, flexible, and deformable curved substrates may be dynamically formed into and out of the curve. It is to be understood that substrates are not limited to curved shapes, but may include any substantially non-flat surface capable of having a transferred thin film block associated therewith according to embodiments of the invention.

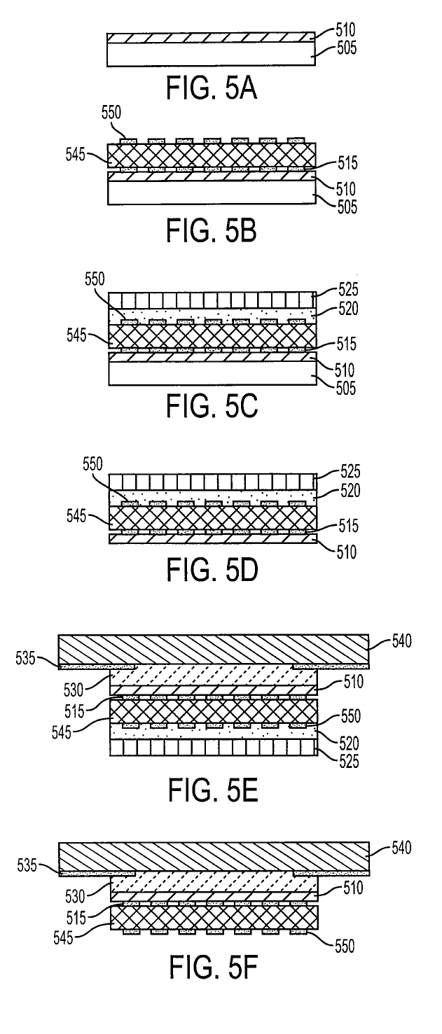

FIG. 5a illustrates an exemplary thin film block having a fabrication sheet with a base layer on a surface of the sheet according to embodiments of the invention. In the example of FIG. 5a, sheet 505 has base layer 510 disposed on a surface. The sheet 505 may include glass or any other suitable material capable of providing a temporary platform on which to fabricate a thin film block and then being easily removed from the block. The base layer 510 may include etch stopping material, such as silicon nitride, silicon dioxide, or any other suitable material that is inert to chemicals, e.g., hydrogen fluoride, that can be used to remove the sheet 505 by chemical etching. The base layer 510 may be deposited on the surface of the sheet 505 with PECVD or any other suitable deposition method. The base layer 510 may be rigid, semi-rigid, flexible, or deformable, depending on the application of the thin film block.

FIG. 5b illustrates the exemplary thin film block shown in FIG. 5a patterned with two separated single layers of thin film on a surface of the base layer according to embodiments of the invention. In the example of FIG. 5b, patterns of thin film 515 may be deposited as a single layer on a surface of the base layer 510. The thin film patterns may be used as conductive traces for carrying signals and may include transparent materials, such as ITO. The thin film patterns may form portions of touch sensors for carrying images of touch in a touch sensitive device, such as a touch panel. The patterned thin film 515 may be deposited on a surface of the base layer 510 using sputtering or any other suitable method for disposing the patterned thin film onto the base layer.

Separation layer 545 may be disposed on the patterned thin film 515. Patterns of thin film 550 may be deposited as a single layer on a surface of the separation layer 545 opposite the surface of the separation layer disposed on the patterned thin film 515. Like the patterned thin film 515, the thin film patterns 550 may be used as conductive traces for carrying signals and may include transparent materials, such as ITO. The thin film patterns may form portions of touch sensors for carrying images of touch in a touch sensitive device, such as a touch panel. The patterned thin film 550 may be deposited on a surface of the separation layer 545 using sputtering or any other suitable method for disposing the patterned thin film onto the separation layer. The separation layer 545 may be rigid, semi-rigid, flexible, or deformable, depending on the application of the thin film block. The separation layer 545 may be glass or some other transparent dielectric material. The patterned thin films 515, 550 may form on opposite sides of the separation layer 545 as double-layer indium tin oxide (DITO).

In an alternate embodiment, the separation layer 545 may be omitted and the patterned thin films 515, 550 may be formed one on top of the other as double SITO.

FIG. 5c illustrates the exemplary thin film block shown in FIG. 5b having a transfer layer adhered to the outermost of the patterned single layers of thin film with a removable adhesive according to embodiments of the invention. In the example of FIG. 5c, a layer of removable adhesive 520 may coat the outermost of the patterned thin films 550. The removable adhesive 520 may include water-insoluble glue or any other suitable material capable of temporarily adhering two layers together and then being dissolved or otherwise removed. Transfer layer 525 may be placed on top of the removable adhesive 520, which helps to adhere the transfer layer to the underlying patterned thin film 515. The transfer layer 525 may include a polymer, such as PET, or any other suitable material capable of supporting a thin film block for transfer to a substrate according to embodiments of the invention. The transfer layer 525 may be laminated or otherwise placed on the removable adhesive 520. The transfer layer 525 may be rigid, semi-rigid, flexible, or deformable, depending on the application of the thin film block.

FIG. 5d illustrates the exemplary thin film block shown in FIG. 5c with the fabrication sheet removed therefrom according to embodiments of the invention. In the example of FIG. 5d, the sheet 505 may be removed in preparation for transferring the thin film block to a substrate. The sheet 505 may be removed by chemical etching using a chemical such as hydrogen fluoride. Alternatively, the sheet 505 may be removed by mechanical methods or combination chemical-mechanical methods.

FIG. 5e illustrates an exemplary substrate having the exemplary thin film block shown in FIG. 5d transferred to a surface of the substrate and adhered thereto with a permanent adhesive according to embodiments of the invention. In the example of FIG. 5e, a layer of permanent adhesive 530 may be laminated or otherwise adhered to the base layer 510 of the thin film block. The permanent adhesive 530 may be adhered to the surface of the base layer 510 opposite the base layer surface onto which the patterned thin film 515 is disposed. The permanent adhesive 530, along with the thin film block, may be laminated or otherwise adhered to a surface of substrate 540. Accordingly, the stacking order may be the substrate 540, the permanent adhesive 530, the base layer 510, the patterned thin film 515, the separation layer 545, the second patterned thin film 550, the removable adhesive 520, and the transfer layer 525. Optionally, opaque material 535 may be adhered to the edges of the substrate 540 and the permanent adhesive 530 to provide an aesthetic border for the substrate. The permanent adhesive 530 may include water-insoluble glue or any other suitable material capable of permanently adhering two layers together. The substrate 540 may include glass, plastic, or any other transparent material. The substrate 540 may be rigid, semi-rigid, flexible, or deformable, depending on the application of the substrate. In some embodiments, the substrate 540 may be a cover material for a touch sensitive device, in which a front side of the substrate 540 can receive a touch and a back side of the substrate can have the thin film block transferred thereto to detect the received touch.

FIG. 5f illustrates the exemplary substrate and thin film block shown in FIG. 5e with the transfer layer removed from the thin film block according to embodiments of the invention. In the example of FIG. 5f, the transfer layer 525 may be removed from the patterned thin film 550 by delaminating or otherwise removing the transfer layer from the removable adhesive 520 and then dissolving or otherwise removing the removable adhesive from the thin film. Alternatively, the removable adhesive 520 may be dissolved or otherwise removed from the thin film 550, thereby removing the transfer layer 525 with it. The resulting substrate and thin film block may now be ready for further processing. In some embodiments, a flex circuit may be bonded to one or both of the patterned thin films 515, 550 at one end and an anti-reflective film may be laminated or otherwise coated over the patterned thin film 550 to further form a touch sensitive device. Optionally, one or more gaskets may be attached to the anti-reflective film to provide connections for other components of the touch sensitive device.

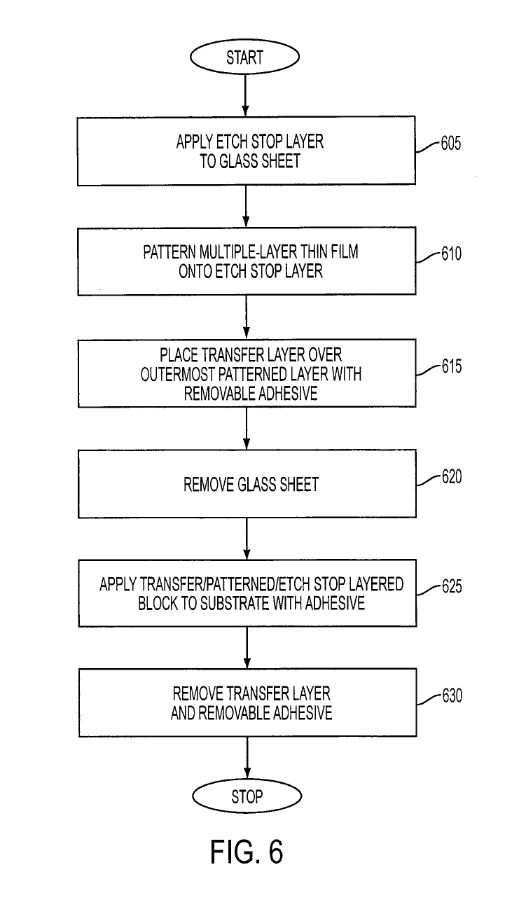

FIG. 6 illustrates an exemplary method for transferring a thin film to a substrate according to embodiments of the invention. A glass sheet may be provided as a temporary platform upon which to fabricate a transferable thin film block. An etch stop layer may be applied to the glass sheet (605). The etch stop layer may be deposited, laminated, or otherwise applied to the sheet. One or more single layers of thin film may be patterned on a surface of the etch stop layer (610). For multiple layers, a separation layer may be deposited between each patterned thin film. The patterned thin film may be SITO, DITO, or double SITO, for example. A transfer layer may be adhered to the outermost of the patterned single layers with a removable adhesive (615). The removable adhesive may be applied to the patterned thin film and then the transfer layer laminated or otherwise placed on top of the removable adhesive.

After the transferable thin film block has been fabricated, the glass sheet may be removed (620). To do so, the thin film block may be exposed to an etching chemical that can etch away the glass sheet. The etch stop layer can protect the rest of the thin film block from chemical damage. Alternatively, a mechanical method may be used to remove the glass sheet. The remaining thin film block, comprising the transfer layer, removable adhesive, one or more patterned thin films, one or more separation layers, and etch stop layer, may be transferred to a substrate and adhered thereto using a permanent adhesive (625). The permanent adhesive may be laminated or otherwise adhered to the etch stop layer and then laminated or otherwise adhered to a surface of the substrate. As such, the etch stop layer may be closest to the substrate, followed by the one or more patterned thin films and separation layers, followed by the removable adhesive, and the transfer layer farthest from the substrate.

The transfer layer and removable adhesive may be removed from the patterned thin film (630). The removable adhesive may be dissolved in solvent or otherwise removed, thereby removing the transfer layer with it. Alternatively, the transfer layer may be delaminated or otherwise removed from the removable adhesive and then the removable adhesive dissolved or otherwise removed from the patterned thin film. The resulting substrate-thin film block combination may be further processed to provide a suitable circuit.

In an alternate embodiment, the etch stop layer may be replaced with a plastic or polyimide layer, which may be bonded to the glass sheet. The glass sheet may then be removed from the thin film block by de-bonding the sheet from the plastic or polyimide layer.

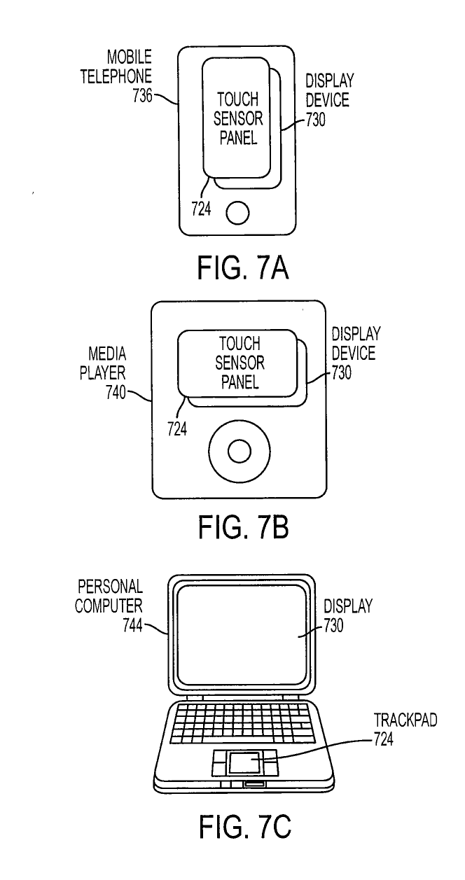

FIG. 7a illustrates an exemplary mobile telephone 736 that can include touch sensor panel 724, display device 730, and other computing system blocks, where the touch sensor panel can have a plurality of co-planar single layer touch sensors fabricated in a single layer on one side of a transfer substrate and transferred to the back side of the touch sensor panel from the transfer substrate.

FIG. 7b illustrates an exemplary digital media player 740 that can include touch sensor panel 724, display device 730, and other computing system blocks, where the touch sensor panel can have a plurality of co-planar single layer touch sensors fabricated in a single layer on one side of a transfer substrate and transferred to the back side of the touch sensor panel from the transfer substrate.

FIG. 7c illustrates an exemplary personal computer 744 that can include touch sensor panel (trackpad) 724 and display 730, and other computing system blocks, where the touch sensor panel can have a plurality of co-planar single layer touch sensors fabricated in a single layer on one side of a transfer substrate and transferred to the back side of the touch sensor panel from the transfer substrate.

The mobile telephone, media player, and personal computer of FIGS. 7a, 7b and 7c can have easily fabricated and transferred touch sensors according to embodiments of the invention.

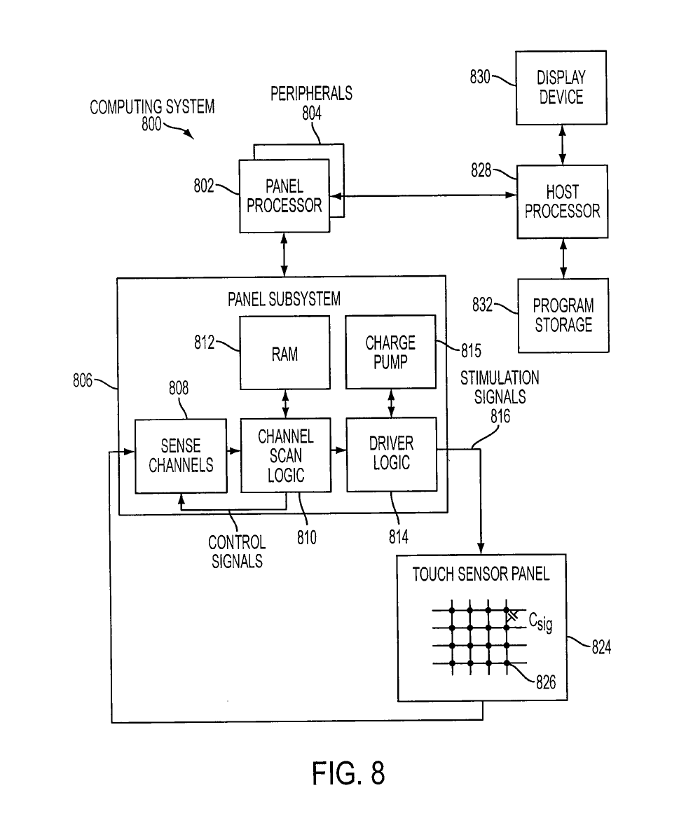

FIG. 8 illustrates exemplary computing system 800 that can include one or more of the embodiments of the invention described above. Computing system 800 can include one or more panel processors 802 and peripherals 804, and panel subsystem 806. Peripherals 804 can include, but are not limited to, random access memory (RAM) or other types of memory or storage, watchdog timers and the like. Panel subsystem 806 can include, but is not limited to, one or more sense channels 808, channel scan logic 810 and driver logic 814. Channel scan logic 810 can access RAM 812, autonomously read data from the sense channels and provide control for the sense channels. In addition, channel scan logic 810 can control driver logic 814 to generate stimulation signals 816 at various frequencies and phases that can be selectively applied to drive lines of touch sensor panel 824. In some embodiments, panel subsystem 806, panel processor 802 and peripherals 804 can be integrated into a single application specific integrated circuit (ASIC).

Touch sensor panel 824 can include a capacitive sensing medium having a plurality of drive lines and a plurality of sense lines, although other sensing media can also be used. Either or both of the drive and sense lines can be fabricated on a transfer substrate and transferred from the transfer substrate to the touch sensor panel according to embodiments of the invention. Each intersection of drive and sense lines can represent a capacitive sensing node and can be viewed as picture element (pixel) 826, which can be particularly useful when touch sensor panel 824 is viewed as capturing an “image” of touch. (In other words, after panel subsystem 806 has determined whether a touch event has been detected at each touch sensor in the touch sensor panel, the pattern of touch sensors in the multi-touch panel at which a touch event occurred can be viewed as an “image” of touch (e.g. a pattern of fingers touching the panel).) Each sense line of touch sensor panel 824 can drive sense channel 808 (also referred to herein as an event detection and demodulation circuit) in panel subsystem 806.

Computing system 800 can also include host processor 828 for receiving outputs from panel processor 802 and performing actions based on the outputs that can include, but are not limited to, moving an object such as a cursor or pointer, scrolling or panning, adjusting control settings, opening a file or document, viewing a menu, making a selection, executing instructions, operating a peripheral device coupled to the host device, answering a telephone call, placing a telephone call, terminating a telephone call, changing the volume or audio settings, storing information related to telephone communications such as addresses, frequently dialed numbers, received calls, missed calls, logging onto a computer or a computer network, permitting authorized individuals access to restricted areas of the computer or computer network, loading a user profile associated with a user's preferred arrangement of the computer desktop, permitting access to web content, launching a particular program, encrypting or decoding a message, and/or the like. Host processor 828 can also perform additional functions that may not be related to panel processing, and can be coupled to program storage 832 and display device 830 such as an LCD panel for providing a UI to a user of the device. Display device 830 together with touch sensor panel 824, when located partially or entirely under the touch sensor panel, can form touch screen 818.

Note that one or more of the functions described above can be performed by firmware stored in memory (e.g. one of the peripherals 804 in FIG. 8) and executed by panel processor 802, or stored in program storage 832 and executed by host processor 828. The firmware can also be stored and/or transported within any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any medium that can contain or store the program for use by or in connection with the instruction execution system, apparatus, or device. The computer readable medium can include, but is not limited to, an electronic, magnetic, optical, electromagnetic, infrared, or semiconductor system, apparatus or device, a portable computer diskette (magnetic), a random access memory (RAM) (magnetic), a read-only memory (ROM) (magnetic), an erasable programmable read-only memory (EPROM) (magnetic), a portable optical disc such a CD, CD-R, CD-RW, DVD, DVD-R, or DVD-RW, or flash memory such as compact flash cards, secured digital cards, USB memory devices, memory sticks, and the like.

The firmware can also be propagated within any transport medium for use by or in connection with an instruction execution system, apparatus, or device, such as a computer-based system, processor-containing system, or other system that can fetch the instructions from the instruction execution system, apparatus, or device and execute the instructions. In the context of this document, a “transport medium” can be any medium that can communicate, propagate or transport the program for use by or in connection with the instruction execution system, apparatus, or device. The transport readable medium can include, but is not limited to, an electronic, magnetic, optical, electromagnetic or infrared wired or wireless propagation medium.

Although the invention has been fully described in connection with embodiments thereof with reference to the accompanying drawings, it is to be noted that various changes and modifications will become apparent to those skilled in the art. Such changes and modifications are to be understood as being included within the scope of the invention as defined by the appended claims.

What is claimed is:

1. A method for transferring a thin film to a substrate, comprising:
applying a base layer to a fabrication sheet;
patterning a single layer of thin film on top of the base layer;
adhering a transfer layer on top of the patterned single layer;
removing the fabrication sheet from the base layer;
transferring the combined base layer, patterned single layer, and transfer layer to a surface of a substrate, the base layer being in contact with the substrate surface; and
removing the transfer layer from the patterned single layer.

2. The method of claim 1, wherein the patterning of the single layer of thin film comprises forming a plurality of portions of conductive material into co-planar touch sensors.

3. The method of claim 1, wherein the adhering of the transfer layer comprises:
depositing a layer of removable adhesive over the patterned single layer; and
placing the transfer layer on top of the removable adhesive layer to adhere to the patterned single layer.

4. The method of claim 1, wherein the removing of the fabrication sheet comprises chemical etching of the fabrication sheet.

5. The method of claim 1, wherein the transferring of the combined base layer, patterned single layer, and transfer layer comprises:
depositing a permanent adhesive on the surface of the substrate; and
placing the base layer on top of the permanent adhesive to adhere the combined base layer, patterned single layer, and transfer layer to the substrate surface.

6. The method of claim 3, wherein the removing of the transfer layer comprises dissolving the removable adhesive in a solvent.

7. The method of claim 1, wherein the base layer includes etch stopping material.

8. The method of claim 1, wherein the single layer of thin film includes a conductive material.

9. The method of claim 8, wherein the conductive material is indium tin oxide (ITO).

10. The method of claim 1, wherein the transfer layer includes a polymer.

11. The method of claim 1, wherein the base layer includes plastic.

12. The method of claim 11, wherein the applying of the base layer comprises bonding the plastic to the fabrication sheet.

13. The method of claim 11, wherein the removing of the fabrication sheet comprises de-bonding the plastic from the fabrication sheet.

14. The method of claim 1, wherein the substrate is a cover material for a touch sensitive device.

15. A method for transferring a thin film to a substrate, comprising:
providing a flexible transfer block on a fabrication sheet comprising
a flexible layer placed on the fabrication sheet,
a patterned single layer of thin film formed on top of the flexible layer, and
a transfer layer adhered on top of the patterned single layer;
removing the fabrication sheet from the flexible layer;
transferring the flexible transfer block to a substrate having a substantially non-flat surface, with the flexible layer adjacent to the substrate; and
removing the transfer layer from the patterned single layer.

16. The method of claim 15, the substantially non-flat surface being a curved surface, wherein the transferring of the flexible transfer block is to the curved surface of the substrate to conform thereto.

17. The method of claim 15, the substantially non-flat surface being a curved surface opposite a substantially flat surface, wherein the transferring of the flexible transfer block is to the substantially flat surface of the substrate.

18. The method of claim 15, the substrate being deformable so as to form the substantially non-flat surface, wherein the flexible transfer block deforms with the substrate so as to conform to the deformable substantially non-flat surface of the substrate.

19. The method of claim 15, the substrate being flexible so as to form the substantially non-flat surface, wherein the flexible transfer block flexes with the substrate so as to conform to the flexible substantially non-flat surface of the substrate.

20. A method for transferring a thin film to a substrate, comprising:
forming a thin film block having a base layer formed on a fabrication sheet, a single layer of thin film forming a pattern on the base layer, and a temporary layer adhered on top of the patterned single layer;
cutting the thin film block into smaller blocks, each smaller block having a portion of the fabrication sheet, a portion of the base layer formed on the portion of the transparent sheet, a portion of the single layer of thin film forming a pattern on the portion of the base layer, and a portion of the temporary layer adhered on top of the portion of the patterned single layer; and
for each smaller block,
removing the portion of the fabrication sheet from the portion of the base layer,
applying the combined portions of the base layer, patterned single layer, and temporary layer to a surface of a cover glass, the portion of the base layer being adhered to the surface of the cover glass, and
removing the portion of the temporary layer from the portion of the patterned single layer.

21. The method of claim 20, further comprising:
for each smaller block, attaching a flex circuit to the portion of the patterned single layer after the removing of the portion of the temporary layer.

22. The method of claim 20, further comprising:
for each smaller block, applying an anti-reflective layer to the portion of the patterned single layer after the removing of the portion of the temporary layer.

23. The method of claim 20, wherein the cover glass has a front surface configured to receive a touch and a back surface opposite the front surface, the back surface being adhered to the portion of the base layer.

24. The method of claim 20, wherein the cover glass and the combined portions of the base layer and patterned single layer form a touch sensitive device.

25. In a system including a sensor panel having a touch surface with a front side configured to receive a touch and a back side opposite the front side, a method for transferring a thin film to the sensor panel, the method comprising:
applying a base layer to a substrate;
patterning at least one single layer of thin film onto the base layer, the at least one single layer of thin film comprising conductive material configured to detect the touch;
adhering a transfer layer on top of the at least one patterned single layer;
removing the substrate from the base layer;
transferring the combined base layer, at least one patterned single layer, and transfer layer to the back side of the touch surface with the base layer being disposed on the back side and the transfer layer being disposed furthest from the back side; and
removing the transfer layer from the at least one patterned single layer.

26. The method of claim 25, wherein the patterning of the at least one single layer of thin film comprises:
patterning a first single layer of thin film onto the base layer;
placing a dielectric material on top of the first patterned single layer of thin film; and
patterning a second single layer of thin film on top of the dielectric material,
wherein the transfer layer is adhered on top of the second patterned single layer.

27. The method of claim 25, wherein the patterning of the at least one single layer of thin film comprises:
patterning a first single layer of thin film onto the base layer;
patterning a second single layer of thin film on top of the first single layer,
wherein the transfer layer is adhered on top of the second patterned single layer.

28. A multi-touch panel comprising:
a touch surface having a front side configured to receive a touch and a back side opposite the front side; and
a plurality of co-planar single layer touch sensors configured to detect the touch, the touch sensors having been fabricated in a single layer on one side of a transfer substrate and transferred to the back side of the touch surface from the one side of the transfer substrate.

29. The multi-touch panel of claim 28 incorporated into a computing system.

30. The multi-touch panel of claim 28 incorporated into a mobile telephone.

31. The multi-touch panel of claim 28 incorporated into a digital media player.

32. A mobile telephone including a touch sensor panel, the touch sensor panel comprising:
a touch surface having a front side configured to receive a touch and a back side opposite the front side; and
a plurality of co-planar single layer touch sensors configured to detect the touch, the touch sensors having been fabricated in a single layer on one side of a transfer substrate and transferred to the back side of the touch surface from the one side of the transfer substrate.

33. A digital media player including a touch sensor panel, the touch sensor panel comprising:
a touch surface having a front side configured to receive a touch and a back side opposite the front side; and
a plurality of co-planar single layer touch sensors configured to detect the touch, the touch sensors having been fabricated in a single layer on one side of a transfer substrate and transferred to the back side of the touch surface from the one side of the transfer substrate.

34. A computer including a touch sensor panel, the touch sensor panel comprising:
a touch surface having a front side configured to receive a touch and a back side opposite the front side; and
a plurality of co-planar single layer touch sensors configured to detect the touch, the touch sensors having been fabricated in a single layer on one side of a transfer substrate and transferred to the back side of the touch surface from the one side of the transfer substrate.
